(19) United States
(12) Patent Application Publication
(10) Pub. No.: US 2005/0170078 A1
(43) Pub. Date: Aug. 4, 2005

(54) Low cost method to form solderable contact points for structures manufactured from conductive loaded resin-based materials

(75) Inventor: Thomas Aisenbrey, Littleton, CO (US)

Correspondence Address: STEPHEN B. ACKERMAN, 28 DAVIS AVENUE, POUGHKEEPSIE, NY, 12603, US

(73) Assignee: Integral Technologies, Inc.

(21) Appl. No.: 11/060,089

(22) Filed: Feb. 17, 2005

Related U.S. Application Data
(63) Continuation-in-part of application No. 10/309,429, filed on Dec. 4, 2002, now Pat. No. 6,870,516.
Application No. 10/309,429 is a continuation-in-part of application No. 10/075,778, filed on Feb. 14, 2002, now Pat. No. 6,741,221.
(60) Provisional application No. 60/552,493, filed on Mar. 12, 2004.
(60) Provisional application No. 60/317,808, filed on Sep. 7, 2001.
(60) Provisional application No. 60/269,414, filed on Feb. 16, 2001.
(60) Provisional application No. 60/268,822, filed on Feb. 15, 2001.

(51) Int. Cl. H05K 3/00

(52) U.S. Cl. 427/98.4

(57) ABSTRACT

Solderable contact points are formed for a conductive device formed of a conductive loaded resin-based material. The conductive loaded resin-based material comprises micron conductive powder(s), conductive fiber(s), or a combination of conductive powder and conductive fibers in a base resin host. The percentage by weight of the conductive powder(s), conductive fiber(s), or a combination thereof is between about 20% and 50% of the weight of the conductive loaded resin-based material. The micron conductive powders are formed from non-metals, such as carbon, graphite, that may also be metallic plated, or the like, or from metals such as stainless steel, nickel, copper, silver, that may also be metallic plated, or the like, or from a combination of non-metal, plated, or in combination with, metal powders. The micron conductor fibers preferably are of nickel plated carbon fiber, stainless steel fiber, copper fiber, silver fiber, aluminum fiber, or the like.

This Patent Application claims priority to the U.S. Provisional Patent Application 60/552,493 filed on Mar. 12, 2004, which is herein incorporated by reference in its entirety.

This Patent Application is a Continuation-in-Part of INT01-002CIP, filed as U.S. patent application Ser. No. 10/309,429, filed on Dec. 4, 2002, also incorporated by reference in its entirety, which is a Continuation-in-Part application of docket number INT01-002, filed as U.S. patent application Ser. No. 10/075,778, filed on Feb. 14, 2002, which claimed priority to U.S. Provisional Patent Applications Ser. No. 60/317,808, filed on Sep. 7, 2001, Ser. No. 60/269,414, filed on Feb. 16, 2001, and Ser. No. 60/268,822, filed on Feb. 15, 2001.

### BACKGROUND OF THE INVENTION

(1) Field of the Invention

This invention relates to molded articles and, more particularly, to a method to provide solderable contact points for articles molded of conductive loaded resin-based materials comprising micron conductive powders, micron conductive fibers, or a combination thereof, substantially homogenized within a base resin when molded. This manufacturing process yields a conductive part or material usable within the EMF or electronic spectrum(s).

(2) Description of the Prior Art

Resin-based polymer materials are used for the manufacture of a wide array of articles. These polymer materials combine many outstanding characteristics, such as excellent strength to weight ratio, corrosion resistance, electrical isolation, and the like, with an ease of manufacture using a variety of well-established molding processes. Many resin-based polymer materials have been introduced into the market to provide useful combinations of characteristics.

Most resin-based polymer materials are poor conductors of thermal and electrical energy. This characteristic is advantageously used in many applications. For example, the handles of metal cooking pans are frequently covered by a molded polymer material to provide a cool handling point for the heated pan. Many electrical interfaces, such as light switches, use resin-based polymers to prevent electrical exposure to the operator. This characteristic can be disadvantageous, however, in extending the use of resin-based polymer materials to applications long dominated by metal materials. For example, it is desirable to reduce weight of electrical and electronic circuit components used in airplanes. These components frequently comprise electrically conductive materials, such as copper, that add substantial weight to an airplane. Replacement of copper with a resin-based material would reduce the weight of the component and, by extension, the entire airplane. Unfortunately, most resin-based materials are not electrically conductive enough to be used as conductors.

Attempts have been made in the art to create intrinsically and non-intrinsically conductive resin-based materials. Intrinsically conductive resin-based materials incorporate molecular structures into the polymer to increase the conductivity of the material. Unfortunately, intrinsically conductive resin-based materials are expensive and provide only limited increases in conductivity. Non-intrinsically conductive resin-based materials are formed by incorporating conductive fillers into the base resin material to impute an increased conductivity to the composite material. Metallic and non-metallic fillers have been demonstrated in the art to provide substantially increased conductivity in the composite material.

In the present invention, a particular conductive loaded resin-based material is described that exhibits excellent bulk conductivity. However, to take advantage of the conductive capabilities of this material, it is useful to have means of electrical contact into the material. More preferably, in an effort to provide compatibility with many electrical and electronics design and manufacturing processes, it is particularly useful to have means of electrical contact to the conductive loaded resin-based material bulk wherein this electrical contact is solderable. A primary purpose of the present invention is to provide solderable contact points for molded conductive loaded resin-based articles.

Several prior art inventions relate to conductive resin-based materials and methods to provide solderable interfaces to said materials. U.S. Pat. No. 6,342,680 B1 to Nakagawa et al teaches a conductive plastic formed of thermoplastic resin, lead-free solder, metal powder or a combination of metal powder and short fibers. U.S. Pat. No. 5,399,295 to Gamble et al teaches an EMI shielding composite comprising a continuous matrix of synthetic resinous material having randomly dispersed therein conductive fibers and a particulate conductive or semi-conductive filler. U.S. Pat. No. 5,789,142 to Brown teaches a method to selectively electroless plate metal onto a resin material wherein a solder mask is used to define the plating areas. U.S. Pat. No. 4,643,798 to Takada et al teaches a method to plate a conductive metallic layer over a resin-based material. The resin-based material may include metal granules. A etch of the resin-based material is performed to exposed the metal granules.

### SUMMARY OF THE INVENTION

A principal object of the present invention is to provide an effective solderable contact point for a conductive loaded resin-based material.

A further object of the present invention is to provide a method to form a solderable contact point to a conductive loaded resin-based material.

A yet further object of the present invention is to provide a solderable contact using molten solder to fill a cavity in the conductive loaded resin-based material.

A yet further object of the present invention is to provide a solderable contact point using a pre-formed solder ring.

A yet further object of the present invention is to provide a solderable contact point using a plating process.

A yet further object of the present invention is to provide a solderable contact point using a solderable ink.

In accordance with the objects of this invention, a conductive device is achieved. The device comprises a molded conductive article comprising a conductive loaded, resin-based material comprising conductive materials in a base resin host. A solderable contact point is formed on the molded conductive article.

Also in accordance with the objects of this invention, a conductive device is achieved. The device comprises a molded conductive article comprising a conductive loaded, resin-based material comprising conductive materials in a base resin host. The percent by weight of the conductive materials is between 20% and 40% of the total weight of the conductive loaded resin-based material. A solderable contact point comprises a cavity in the conductive loaded, resin-based material that is lined with a solderable layer.

Also in accordance with the objects of this invention, a conductive device is achieved. The device comprises a molded conductive article comprising a conductive loaded, resin-based material comprising micron conductive fiber in a base resin host. The percent by weight of the micron conductive fiber is between 20% and 40% of the total weight of the conductive loaded resin-based material. A solderable contact point comprises a solderable layer overlying the conductive loaded, resin-based material.

Also in accordance with the objects of this invention, a method to form a conductive device is achieved. The method comprises providing a conductive loaded, resin-based material comprising conductive materials in a resin-based host. The conductive loaded, resin-based material is molded into a conductive device. A solderable contact point is formed on the conductive device.

Also in accordance with the objects of this invention, a method to form a conductive device is achieved. The method comprises providing a conductive loaded, resin-based material comprising conductive materials in a resin-based host. The percent by weight of the conductive materials is between 20% and 40% of the total weight of the conductive loaded resin-based material. The conductive loaded, resin-based material is molded into a conductive device. A cavity is formed in the conductive loaded, resin-based material. The cavity is lined with a solderable material

Also in accordance with the objects of this invention, a method to form a conductive device is achieved. The method comprises providing a conductive loaded, resin-based material comprising micron conductive fibers in a resin-based host. The percent by weight of the micron conductive fibers is between 20% and 40% of the total weight of the conductive loaded resin-based material. The conductive loaded, resin-based material is molded into a conductive device. A solderable material is formed overlying the conductive device.

### BRIEF DESCRIPTION OF THE DRAWINGS

In the accompanying drawings forming a material part of this description, there is shown:

FIGS. 1a and 1b illustrate a first preferred embodiment of the present invention an article molded of the conductive loaded resin-based material and, more particularly, illustrates a method to form solderable contact points in this molded article.

FIG. 2 illustrates a first preferred embodiment of a conductive loaded resin-based material wherein the conductive materials comprise a powder.

FIG. 3 illustrates a second preferred embodiment of a conductive loaded resin-based material wherein the conductive materials comprise micron conductive fibers.

FIG. 4 illustrates a third preferred embodiment of a conductive loaded resin-based material wherein the conductive materials comprise both conductive powder and micron conductive fibers.

FIGS. 5a and 5b illustrate a fourth preferred embodiment wherein conductive fabric-like materials are formed from the conductive loaded resin-based material.

FIGS. 6a and 6b illustrate, in simplified schematic form, an injection molding apparatus and an extrusion molding apparatus that may be used to mold articles of a conductive loaded resin-based material.

FIGS. 7a, 7b, 7c and 7d illustrate a second preferred embodiment of the present invention showing a circuit board or interface wherein the solderable contact points are formed by either mechanical insertion of pre-shaped solder fillets or by flowing molten solder into cavities in the substrate

FIGS. 8a, 8b, and 8c illustrate a third preferred embodiment of the present invention showing a circuit board or interface wherein the solderable contact points are formed by forming a metal thin film to line the cavities and then by filing the cavities with solder.

FIGS. 9a, 9b, and 9c illustrates a fourth preferred embodiment of the present invention showing a first EMI shielding can molded from a conductive loaded resin-based material according to the present invention and, further comprising, a plated solderable interface.

FIGS. 10a and 10b illustrate a fifth preferred embodiment of the present invention showing a second EMI shielding can molded from a conductive loaded resin-based material according to the present invention and, further comprising, a plated solderable interface.

FIG. 11 illustrates a sixth preferred embodiment of the present invention showing a simplified antenna element formed according to the present invention.

FIG. 12 illustrates a seventh preferred embodiment of the present invention showing a solderable contact point formed by inserting a solderable screw into the conductive loaded resin-based material, post-molding.

FIG. 13 illustrates an eighth preferred embodiment of the present invention showing a solderable contact point formed by molding a solderable pin into the conductive loaded resin-based material.

### DESCRIPTION OF THE PREFERRED EMBODIMENTS

This invention relates to articles molded of conductive loaded resin-based materials comprising micron conductive powders, micron conductive fibers, or a combination thereof, substantially homogenized within a base resin when molded.

The conductive loaded resin-based materials of the invention are base resins loaded with conductive materials, which then makes any base resin a conductor rather than an insulator. The resins provide the structural integrity to the molded part. The micron conductive fibers, micron conductive powders, or a combination thereof, are substantially homogenized within the resin during the molding process, providing the electrical continuity.

The conductive loaded resin-based materials can be molded, extruded or the like to provide almost any desired shape or size. The molded conductive loaded resin-based materials can also be cut, stamped, or vacuumed formed from an injection molded or extruded sheet or bar stock, over-molded, laminated, milled or the like to provide the desired shape and size. The thermal or electrical conductivity characteristics of articles fabricated using conductive loaded resin-based materials depend on the composition of the conductive loaded resin-based materials, of which the loading or doping parameters can be adjusted, to aid in achieving the desired structural, electrical or other physical characteristics of the material. The selected materials used to fabricate the articles are substantially homogenized together using molding techniques and or methods such as injection molding, over-molding, insert molding, thermoset, protrusion, extrusion or the like. Characteristics related to 2D, 3D, 4D, and 5D designs, molding and electrical characteristics, include the physical and electrical advantages that can be achieved during the molding process of the actual parts and the polymer physics associated within the conductive networks within the molded part(s) or formed material(s).

In the conductive loaded resin-based material, electrons travel from point to point when under stress, following the path of least resistance. Most resin-based materials are insulators and represent a high resistance to electron passage. The doping of the conductive loading into the resin-based material alters the inherent resistance of the polymers. At a threshold concentration of conductive loading, the resistance through the combined mass is lowered enough to allow electron movement. Speed of electron movement depends on conductive loading concentration, that is, the separation between the conductive loading particles. Increasing conductive loading content reduces interparticle separation distance, and, at a critical distance known as the percolation point, resistance decreases dramatically and electrons move rapidly.

The use of conductive loaded resin-based materials in the fabrication of articles significantly lowers the cost of materials and the design and manufacturing processes used to hold ease of close tolerances, by forming these materials into desired shapes and sizes. The articles can be manufactured into infinite shapes and sizes using conventional forming methods such as injection molding, over-molding, or extrusion or the like. The conductive loaded resin-based materials, when molded, typically but not exclusively produce a desirable usable range of resistivity from between about 5 and 25 ohms per square, but other resistivities can be achieved by varying the doping parameters and/or resin selection(s).

The conductive loaded resin-based materials comprise micron conductive powders, micron conductive fibers, or any combination thereof, which are substantially homogenized together within the base resin, during the molding process, yielding an easy to produce low cost, electrically conductive, close tolerance manufactured part or circuit. The resulting molded article comprises a three dimensional, continuous network of conductive loading and polymer matrix. The micron conductive powders can be of carbons, graphites, amines or the like, and/or of metal powders such as nickel, copper, silver, aluminum, or plated or the like. The use of carbons or other forms of powders such as graphite(s) etc. can create additional low level electron exchange and, when used in combination with micron conductive fibers, creates a micron filler element within the micron conductive network of fiber(s) producing further electrical conductivity as well as acting as a lubricant for the molding equipment. The micron conductive fibers can be nickel plated carbon fiber, stainless steel fiber, copper fiber, silver fiber, aluminum fiber, or the like, or combinations thereof. The structural material is a material such as any polymer resin. Structural material can be, here given as examples and not as an exhaustive list, polymer resins produced by GE PLASTICS, Pittsfield, Mass., a range of other plastics produced by GE PLASTICS, Pittsfield, Mass., a range of other plastics produced by other manufacturers, silicones produced by GE SILICONES, Waterford, N.Y., or other flexible resin-based rubber compounds produced by other manufacturers.

The resin-based structural material loaded with micron conductive powders, micron conductive fibers, or in combination thereof can be molded, using conventional molding methods such as injection molding or over-molding, or extrusion to create desired shapes and sizes. The molded conductive loaded resin-based materials can also be stamped, cut or milled as desired to form create the desired shape form factor(s) of the articles. The doping composition and directionality associated with the micron conductors within the loaded base resins can affect the electrical and structural characteristics of the articles and can be precisely controlled by mold designs, gating and or protrusion design(s) and or during the molding process itself. In addition, the resin base can be selected to obtain the desired thermal characteristics such as very high melting point or specific thermal conductivity.

A resin-based sandwich laminate could also be fabricated with random or continuous webbed micron stainless steel fibers or other conductive fibers, forming a cloth like material. The webbed conductive fiber can be laminated or the like to materials such as Teflon, Polyesters, or any resin-based flexible or solid material(s), which when discretely designed in fiber content(s), orientation(s) and shape(s), will produce a very highly conductive flexible cloth-like material. Such a cloth-like material could also be used in forming articles that could be embedded in a person's clothing as well as other resin materials such as rubber(s) or plastic(s). When using conductive fibers as a webbed conductor as part of a laminate or cloth-like material, the fibers may have diameters of between about 3 and 12 microns, typically between about 8 and 12 microns or in the range of about 10 microns, with length(s) that can be seamless or overlapping.

The conductive loaded resin-based material of the present invention can be made resistant to corrosion and/or metal electrolysis by selecting micron conductive fiber and/or micron conductive powder and base resin that are resistant to corrosion and/or metal electrolysis. For example, if a corrosion/electrolysis resistant base resin is combined with stainless steel fiber and carbon fiber/powder, then a corrosion and/or metal electrolysis resistant conductive loaded resin-based material is achieved. Another additional and important feature of the present invention is that the conductive loaded resin-based material of the present invention may be made flame retardant. Selection of a flame-retardant (FR) base resin material allows the resulting product to exhibit flame retardant capability. This is especially important in applications as described herein.

The substantially homogeneous mixing of micron conductive fiber and/or micron conductive powder and base resin described in the present invention may also be described as doping. That is, the substantially homogeneous mixing converts the typically non-conductive base resin material into a conductive material. This process is analogous to the doping process whereby a semiconductor material, such as silicon, can be converted into a conductive material through the introduction of donor/acceptor ions as is well known in the art of semiconductor devices. Therefore, the present invention uses the term doping to mean converting a typically non-conductive base resin material into a conductive material through the substantially homogeneous mixing of micron conductive fiber and/or micron conductive powder into a base resin.

As an additional and important feature of the present invention, the molded conductor loaded resin-based material exhibits excellent thermal dissipation characteristics. Therefore, articles manufactured from the molded conductor loaded resin-based material can provide added thermal dissipation capabilities to the application. For example, heat can be dissipated from electrical devices physically and/or electrically connected to articles of the present invention.

As a significant advantage of the present invention, articles constructed of the conductive loaded resin-based material can be easily interfaced to an electrical circuit or grounded. In one embodiment, a wire can be attached to the conductive loaded resin-based material via a screw that is fastened to the conductive loaded resin-based material. For example, a simple sheet-metal type, self tapping screw, when fastened to the material, can achieve excellent electrical connectivity via the conductive matrix of the conductive loaded resin-based material. To facilitate this approach a boss may be molded into the conductive loaded resin-based material to accommodate such a screw. Alternatively, if a solderable screw material, such as copper, is used, then a wire can be soldered to the screw that is embedded into the conductive loaded resin-based material. In another embodiment, the conductive loaded resin-based material is partly or completely plated with a metal layer. The metal layer forms excellent electrical conductivity with the conductive matrix. A connection of this metal layer to another circuit or to ground is then made. For example, if the metal layer is solderable, then a soldered connection may be made between the molded article and a grounding wire.

A typical metal deposition process for forming a metal layer onto the conductive loaded resin-based material is vacuum metallization. Vacuum metallization is the process where a metal layer, such as aluminum, is deposited on the conductive loaded resin-based material inside a vacuum chamber. In a metallic painting process, metal particles, such as silver, copper, or nickel, or the like, are dispersed in an acrylic, vinyl, epoxy, or urethane binder. Most resin-based materials accept and hold paint well, and automatic spraying systems apply coating with consistency. In addition, the excellent conductivity of the conductive loaded resin-based material of the present invention facilitates the use of extremely efficient, electrostatic painting techniques.

The conductive loaded resin-based material can be contacted in any of several ways. In one embodiment, a pin is embedded into the conductive loaded resin-based material by insert molding, ultrasonic welding, pressing, or other means. A connection with a metal wire can easily be made to this pin and results in excellent contact to the conductive loaded resin-based material. In another embodiment, a hole is formed in to the conductive loaded resin-based material either during the molding process or by a subsequent process step such as drilling, punching, or the like. A pin is then placed into the hole and is then ultrasonically welded to form a permanent mechanical and electrical contact. In yet another embodiment, a pin or a wire is soldered to the conductive loaded resin-based material. In this case, a hole is formed in the conductive loaded resin-based material either during the molding operation or by drilling, stamping, punching, or the like. A solderable layer is then formed in the hole. The solderable layer is preferably formed by metal plating. A conductor is placed into the hole and then mechanically and electrically bonded by point, wave, or reflow soldering.

Another method to provide connectivity to the conductive loaded resin-based material is through the application of a solderable ink film to the surface. One exemplary solderable ink is a combination of copper and solder particles in an epoxy resin binder. The resulting mixture is an active, screen-printable and dispensable material. During curing, the solder reflows to coat and to connect the copper particles and to thereby form a cured surface that is directly solderable without the need for additional plating or other processing steps. Any solderable material may then be mechanically and/or electrically attached, via soldering, to the conductive loaded resin-based material at the location of the applied solderable ink. Many other types of solderable inks can be used to provide this solderable surface onto the conductive loaded resin-based material of the present invention. Another exemplary embodiment of a solderable ink is a mixture of one or more metal powder systems with a reactive organic medium. This type of ink material is converted to solderable pure metal during a low temperature cure without any organic binders or alloying elements.

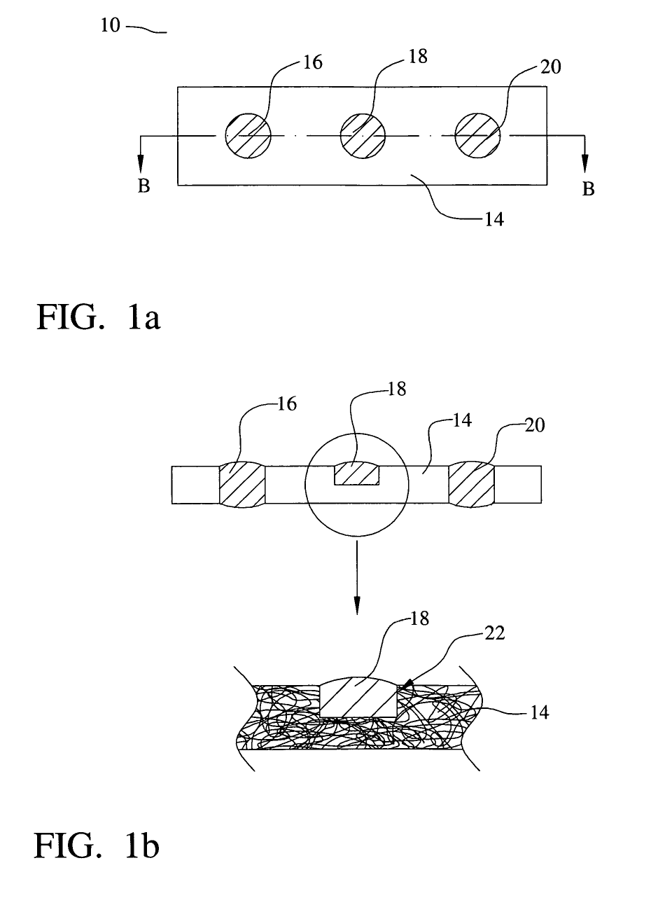

Referring now to FIGS. 1a and 1b, a first preferred embodiment of the present invention is illustrated. An article 10 formed of conductive loaded resin-based material according to the present invention is shown. More particularly, a conductive loaded resin-based article, or device, 10 with solderable contact points 16, 18, and 20 is illustrated. The solderable contact points 16, 18, and 20 each comprise a cavity in the board/substrate 14 that is filled with solder. The cavities may extend partially through or entirely through the board/substrate 14 as shown in the cross sectional FIG. 1b. The solder 16, 18, and 20 bonds with and secures itself to the conductive network 22 of micron conductive fibers and/or micron conductive powders and the base resin within the molded structure 14.

The solder filled cavities 16, 18, and 20 form structurally sound and very solderable contact points to the board/substrate 14. As shown in the inset, the solder 18 mates and interconnects efficiently to the conductive network within the conductive loaded resin-based material. To use an anatomical analogy, this connection may be thought of as providing a large artery, the solderable contact point 18, to connect to and to transport energy to/from a large mass of small capillaries, the network 22 of micron conductive fibers and/or micron conductive powders. The mass of small arteries are fed and extracted upon by the vein creating an exchange of free electrons and electrical forces that is maximized evenly and that exhibits a reduced resistance.

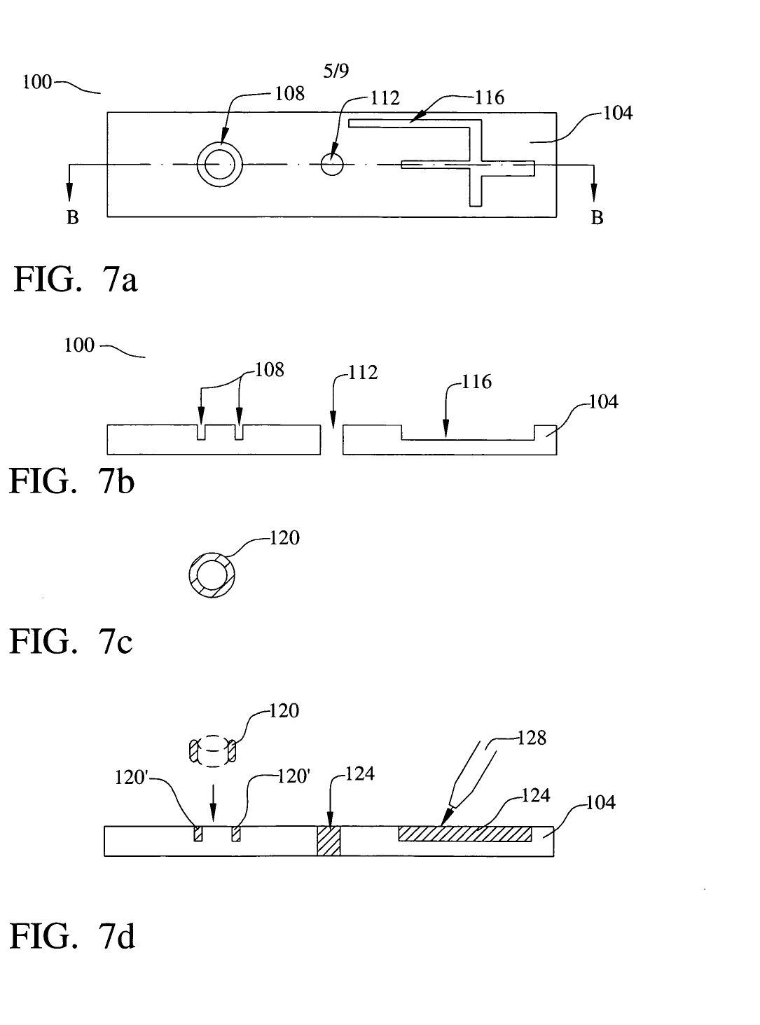

Referring now to FIGS. 7a, 7b, 7c, and 7d, a second preferred embodiment of the present invention is illustrated. A method 100 is shown to form solderable contact points 120′ and 124 in the circuit board or interface 104 of the conductive loaded resin-based material according to the present invention. According to this embodiment, the circuit board or interface substrate 104 is molded from conductive loaded resin-based materials as described herein. As a particularly important feature, cavities 108, 112, and 116 are formed in the board or substrate 104. These cavities may be formed is any of several ways. In one embodiment, cavities 108, 112, and 116 are molded into the board or substrate 104 during the molding process. In other embodiments, the cavities 108, 112, and 116 are formed, after molding, by drilling, punching, milling, or stamping. Some cavities 112 are formed entirely through the board or substrate 104, while other cavities 108 and 116 are formed partially through as is shown on FIG. 7b. The cavities are formed in any shape or size as shown in the top view of FIG. 7a.

After the cavities 108, 112, and 116 are formed in the conductive loaded resin-based material article 104, the cavities are filled with solder as shown in FIG. 7d. Two distinct methods of filling the cavities are illustrated in this view. In one method, a pre-shaped solder 120, in this case a solder ring 120, is provided as shown in FIG. 7c. This solder ring 120 is pressure fit into the ring shaped opening 108 to fill the cavity 120′ as shown in FIG. 7c. After plugging the cavity 120′, the pre-shaped solder is melted, or reflowed, to insure excellent bonding to the micron conductive fibers and/or micron conductive powders and to the resin base. In a second method, the cavity 116 is filled by flowing 128 molten solder 124.

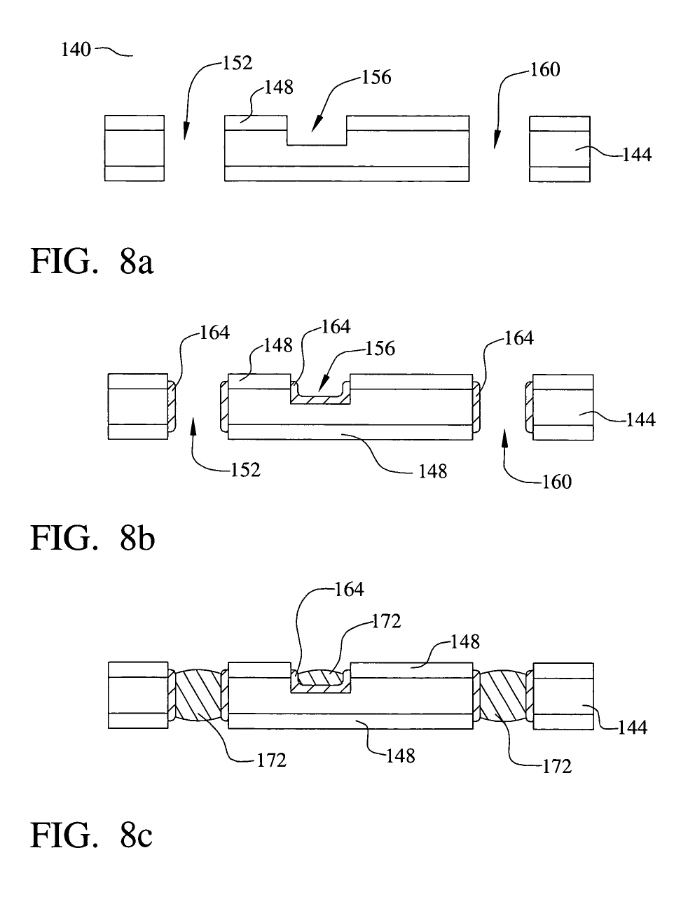

Referring now to FIGS. 8a, 8b, and 8c, a third preferred embodiment of the present invention is illustrated. Another method of forming solderable contact points 172 is shown. Referring particularly to FIG. 8a, a board/substrate 144 is again molded from conductive loaded resin-based materials. Again, cavities 152, 156, and 160 are formed in the board/substrate 144 using any of the methods described above. In an optional embodiment, a solder mask layer 148 is formed overlying the board/substrate 144 while revealing the cavities 152, 156, and 160. This solder mask layer 148 facilitates subsequent depositing of solder into the cavities using a solder wave process. However, a solder mask layer may not be needed depending on the type base resin used.

Referring now to FIG. 8b, a layer of conductive platable material 164 is formed onto the sidewalls of the cavity openings 152, 156, and 160. This conductive platable material thin film 164 may be formed by plating or by vapor deposition. The presence of the optional solder mask layer 148 restricts the conductive platable material thin film 164 formation to the exposed cavities. Optionally, a copper, or other conductive metal, thin film, not shown, may be first formed, by vapor deposition or by plating, onto the cavity sidewalls prior to the conductive platable material thin film 164. Referring now to FIG. 8c, solder 172 is deposited into the cavities 152, 156, and 160. This solder 172 may be deposited by solder vapor deposition or by passing the board/substrate 144 over a molten solder wave. The solder thin film 164 provides an excellent surface for solder bonding.

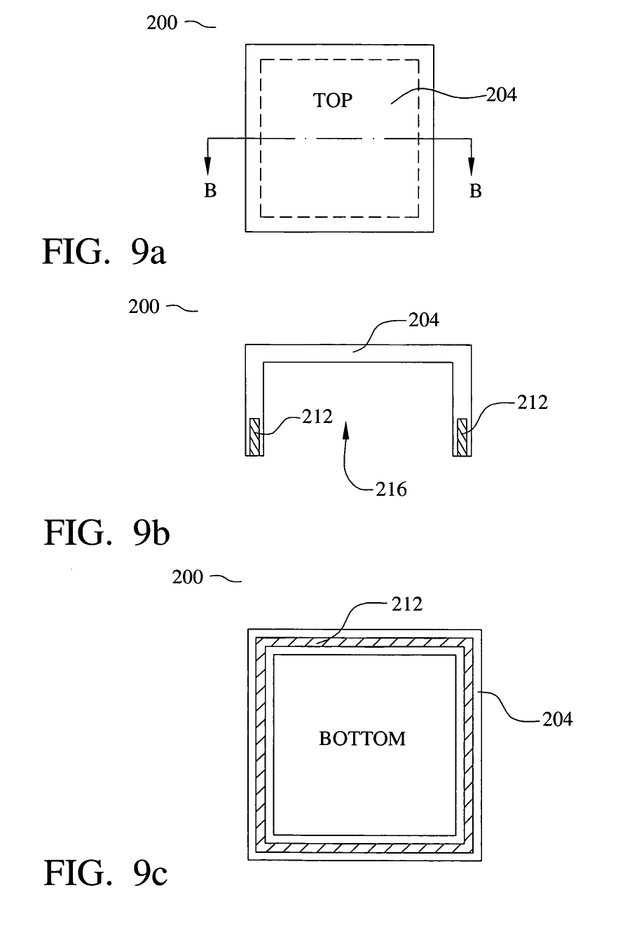

Referring now to FIGS. 9a, 9b, and 9c, a fourth preferred embodiment of the present invention is illustrated. A conductive loaded resin-based shielding can 204 of the present invention is shown. In this case, an electromagnetic interference (EMI) shielding can 204 is molded from the conductive loaded resin-based material described herein. The shielding can 204 is designed to absorb electromagnetic energy. The shielding can 204 is shown in top view in FIG. 9a, in cross section in FIG. 9b, and in bottom view in FIG. 9c. The shielding can 204 is hollow, as can be seen in the cross sectional view, such that it can cover and enclose electronic devices lying underneath the can 204. By forming the shielding can 204 from conductive loaded resin-based materials comprising micron conductive fibers and/or micron conductive particles in a resin base, the resulting can 204 exhibits excellent EMI absorption. EMI energy radiated, whether radiated by enclosed devices or by devices external to the enclosed devices, is absorbed by the can 204 and can then be conducted to ground.

A particular feature of the present invention is the formation of solderable contact points 212 in the sidewalls of the can 204. The solderable contact points 212 may be formed using any of the methods described above. Solder 212 fills a cavity that is formed on the bottom surface sidewall of the can 204 as shown in the bottom view.

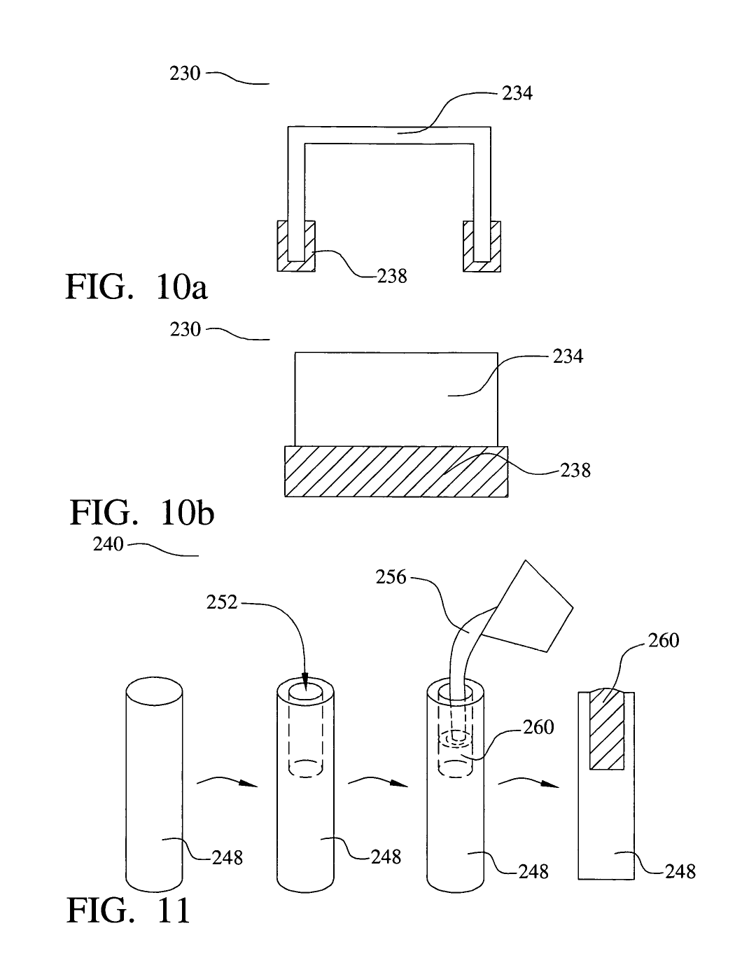

Referring now to FIGS. 10a and 10b, a fifth preferred embodiment 230 of the present invention is illustrated. Another shielding can 234 is shown. Again, the shielding can 234 is molded of conductive loaded resin-based material as described herein. However, in this case, the sidewalls are too thin to facilitate a solder filled cavity within the sidewall. Therefore, solderable material 238 is formed onto the bottom edge and/or part of the lower sidewalls of the can 234. By forming the solderable material 238 partly up the sidewall of the can 234 the structural stability of the solder joint is enhanced. In one embodiment, a conductive platable material 238 is plated onto the can 234. In another embodiment, a solderable ink 238 is applied to the can 234.

Referring now to FIG. 11, a sixth preferred embodiment of the present invention is illustrated. An antenna 248 molded of conductive loaded resin-based material is shown. A cavity 252 is formed in the base of the antenna 248 either during the molding process or by a post-molding process such as drilling. The cavity 252 is then potted with molten solder 256. As a result, a very conductive, solid solder antenna terminal 260 is formed in the antenna 248.

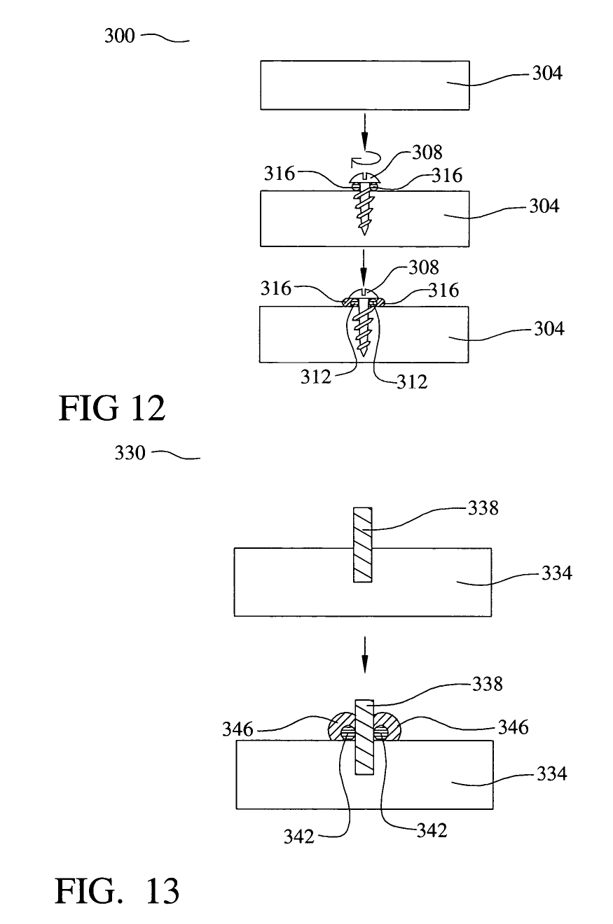

Referring now to FIG. 12, a seventh preferred embodiment 300 of the present invention is illustrated. Another method 300 of forming a solderable contact point is shown. An article 304 is first molded of the conductive loaded resin-based material. Next, a solderable screw 308 is inserted into the article 304. For example, a screw 308 of copper or of a copper or silver coating, or the like, can accept soldering. In the illustrative embodiment, a contact ring 312 is held in place by the screw 308. Finally, a soldering step is used to mechanically and electrically connect the contact ring to the conductive loaded resin-based material article through the screw 308. In another embodiment, a solderable pin may be inserted into the conductive loaded resin-based article 304, post-molding, by heating the article 304 and pressing the pin into place.

Referring now to FIG. 13, an eighth preferred embodiment 330 of the present invention is illustrated. Another method of forming a solderable contact point is shown. A solderable pin 338 is molded into the conductive loaded resin-based article 334. A soldering step is used to mechanically and electrically connect a contact ring 342 to the conductive loaded resin-based material article through the solderable pin 338.

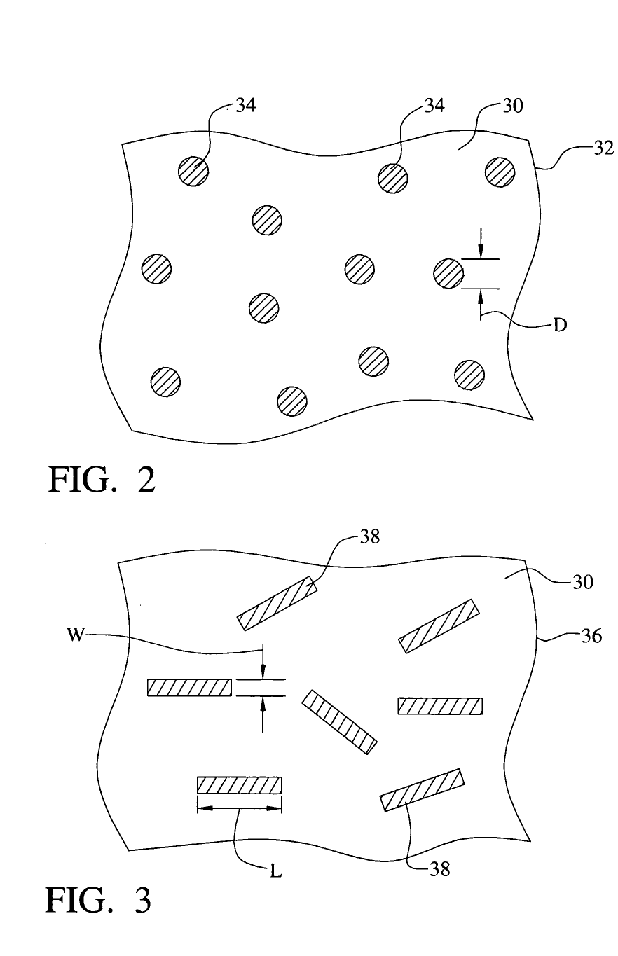

The conductive loaded resin-based material of the present invention typically comprises a micron powder(s) of conductor particles and/or in combination of micron fiber(s) substantially homogenized within a base resin host. FIG. 2 shows cross section view of an example of conductor loaded resin-based material 32 having powder of conductor particles 34 in a base resin host 30. In this example the diameter D of the conductor particles 34 in the powder is between about 3 and 12 microns.

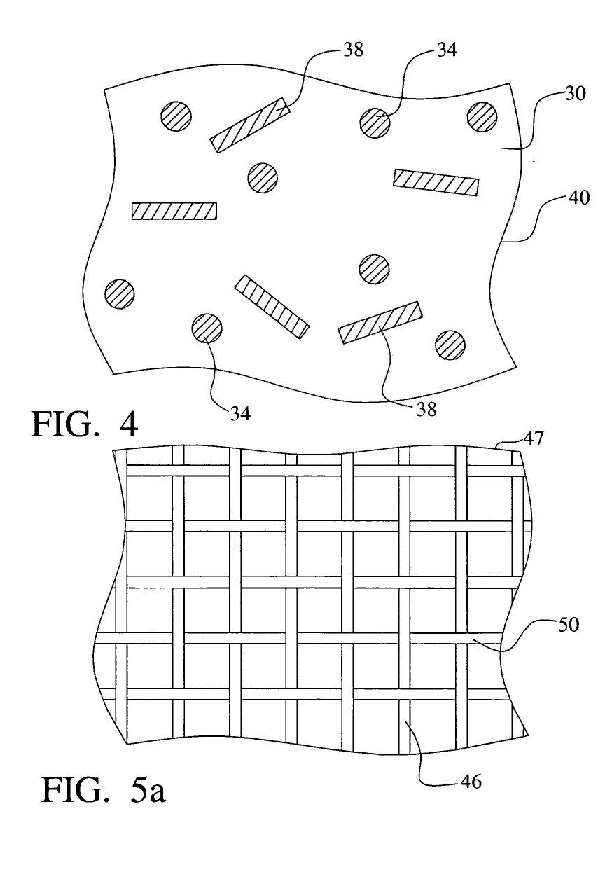

FIG. 3 shows a cross section view of an example of conductor loaded resin-based material 36 having conductor fibers 38 in a base resin host 30. The conductor fibers 38 have a diameter of between about 3 and 12 microns, typically in the range of 10 microns or between about 8 and 12 microns, and a length of between about 2 and 14 millimeters. The conductors used for these conductor particles 34 or conductor fibers 38 can be stainless steel, nickel, copper, silver, aluminum, or other suitable metals or conductive fibers, or combinations thereof. These conductor particles and or fibers are substantially homogenized within a base resin. As previously mentioned, the conductive loaded resin-based materials have a sheet resistance between about 5 and 25 ohms per square, though other values can be achieved by varying the doping parameters and/or resin selection. To realize this sheet resistance the weight of the conductor material comprises between about 20% and about 50% of the total weight of the conductive loaded resin-based material. More preferably, the weight of the conductive material comprises between about 20% and about 40% of the total weight of the conductive loaded resin-based material. More preferably yet, the weight of the conductive material comprises between about 25% and about 35% of the total weight of the conductive loaded resin-based material. Still more preferably yet, the weight of the conductive material comprises about 30% of the total weight of the conductive loaded resin-based material. Stainless Steel Fiber of 6-12 micron in diameter and lengths of 4-6 mm and comprising, by weight, about 30% of the total weight of the conductive loaded resin-based material will produce a very highly conductive parameter, efficient within any EMF spectrum. Referring now to FIG. 4, another preferred embodiment of the present invention is illustrated where the conductive materials comprise a combination of both conductive powders 34 and micron conductive fibers 38 substantially homogenized together within the resin base 30 during a molding process.

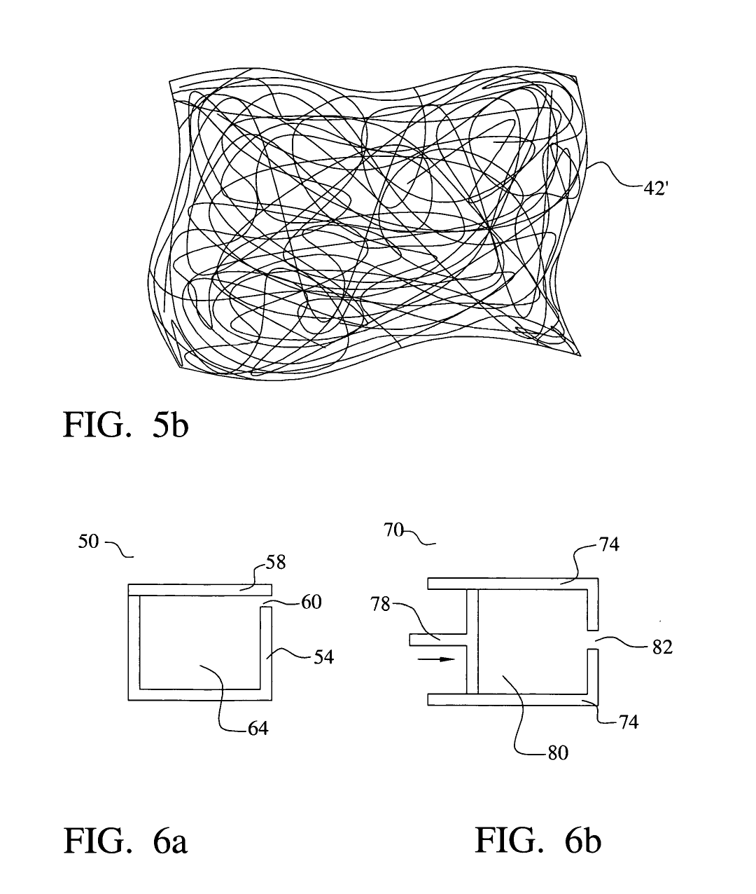

Referring now to FIGS. 5a and 5b, a preferred composition of the conductive loaded, resin-based material is illustrated. The conductive loaded resin-based material can be formed into fibers or textiles that are then woven or webbed into a conductive fabric. The conductive loaded resin-based material is formed in strands that can be woven as shown. FIG. 5a shows a conductive fabric 42 where the fibers are woven together in a two-dimensional weave 46 and 50 of fibers or textiles. FIG. 5b shows a conductive fabric 42′ where the fibers are formed in a webbed arrangement. In the webbed arrangement, one or more continuous strands of the conductive fiber are nested in a random fashion. The resulting conductive fabrics or textiles 42, see FIG. 5a, and 42′, see FIG. 5b, can be made very thin, thick, rigid, flexible or in solid form(s).

Similarly, a conductive, but cloth-like, material can be formed using woven or webbed micron stainless steel fibers, or other micron conductive fibers. These woven or webbed conductive cloths could also be sandwich laminated to one or more layers of materials such as Polyester(s), Teflon(s), Kevlar(s) or any other desired resin-based material(s). This conductive fabric may then be cut into desired shapes and sizes.

Molded articles formed from conductive loaded resin-based materials can be formed or molded in a number of different ways including injection molding, extrusion or chemically induced molding or forming. FIG. 6a shows a simplified schematic diagram of an injection mold showing a lower portion 54 and upper portion 58 of the mold 50. Conductive loaded blended resin-based material is injected into the mold cavity 64 through an injection opening 60 and then the substantially homogenized conductive material cures by thermal reaction. The upper portion 58 and lower portion 54 of the mold are then separated or parted and the articles are removed.

FIG. 6b shows a simplified schematic diagram of an extruder 70 for forming articles using extrusion. Conductive loaded resin-based material(s) is placed in the hopper 80 of the extrusion unit 74. A piston, screw, press or other means 78 is then used to force the thermally molten or a chemically induced curing conductive loaded resin-based material through an extrusion opening 82 which shapes the thermally molten curing or chemically induced cured conductive loaded resin-based material to the desired shape. The conductive loaded resin-based material is then fully cured by chemical reaction or thermal reaction to a hardened or pliable state and is ready for use. Thermoplastic or thermosetting resin-based materials and associated processes may be used in molding the conductive loaded resin-based articles of the present invention.

The advantages of the present invention may now be summarized. An effective solderable contact point for a conductive loaded resin-based material is achieved. A method to form a solderable contact point to a conductive loaded resin-based material is achieved. A solderable contact is achieved using molten solder to fill a cavity in the conductive loaded resin-based material. A solderable contact point is achieved using a pre-formed solder ring. A solderable contact point is achieved using a plating process. A solderable contact point is achieved using a solderable ink.

As shown in the preferred embodiments, the novel methods and devices of the present invention provide an effective and manufacturable alternative to the prior art.

While the invention has been particularly shown and described with reference to the preferred embodiments thereof, it will be understood by those skilled in the art that various changes in form and details may be made without departing from the spirit and scope of the invention.

1. A conductive device comprising:
a molded conductive article comprising a conductive loaded, resin-based material comprising conductive materials in a base resin host; and
a solderable contact point on said molded conductive article.

2. The device according to claim 1 wherein the percent by weight of said conductive materials is between about 20% and about 50% of the total weight of said conductive loaded resin-based material.

3. The device according to claim 1 wherein said conductive materials comprise micron conductive fiber.

4. The device according to claim 2 wherein said conductive materials further comprise conductive powder.

5. The device according to claim 1 wherein said conductive materials are metal.

6. The device according to claim 1 wherein said conductive materials are non-conductive materials with metal plating.

7. The device according to claim 1 wherein said solderable contact point comprises a cavity in said conductive loaded, resin-based material that is lined with a solderable layer.

8. The device according to claim 7 wherein said cavity comprises a hole through said conductive loaded, resin-based material.

10. The device according to claim 7 wherein said cavity comprises a hole partially through said conductive loaded, resin-based material.

11. The device according to claim 1 wherein said solderable contact point comprises a solderable layer overlying said conductive loaded, resin-based material.

12. A conductive device comprising:
a molded conductive article comprising a conductive loaded, resin-based material comprising conductive materials in a base resin host wherein the percent by weight of said conductive materials is between 20% and 40% of the total weight of said conductive loaded resin-based material; and
a solderable contact point comprising a cavity in said conductive loaded, resin-based material that is lined with a solderable layer.

13. The device according to claim 12 wherein said conductive materials are nickel plated carbon micron fiber, stainless steel micron fiber, copper micron fiber, silver micron fiber or combinations thereof.

14. The device according to claim 12 wherein said conductive materials comprise micron conductive fiber and conductive powder.

15. The device according to claim 14 wherein said conductive powder is nickel, copper, or silver.

16. The device according to claim 14 wherein said conductive powder is a non-conductive material with a metal plating of nickel, copper, silver, or alloys thereof.

17. The device according to claim 12 wherein said solderable layer comprises solder.

18. The device according to claim 17 wherein said solderable contact point further comprises a metal layer or a solderable ink layer between said solder and said conductive loaded, resin-based material.

19. The device according to claim 12 wherein said solderable layer is a plated metal layer or a vapor deposited metal layer.

20. The device according to claim 12 wherein said solderable layer is a solderable ink.

21. A conductive device comprising:
a molded conductive article comprising a conductive loaded, resin-based material comprising micron conductive fiber in a base resin host wherein the percent by weight of said micron conductive fiber is between 20% and 40% of the total weight of said conductive loaded resin-based material; and
a solderable contact point comprising a solderable layer overlying said conductive loaded, resin-based material.

22. The device according to claim 21 wherein said micron conductive fiber is stainless steel.

23. The device according to claim 21 wherein said micron conductive fiber has a diameter of between about 3 μm and about 12 μm and a length of between about 2 mm and about 14 mm.

24. The device according to claim 21 wherein said solderable layer is a plated metal layer or a vapor deposited metal layer.

25. The device according to claim 21 wherein said solderable layer is a solderable ink.
